(19) United States
(12) Patent Application Publication
(10) Pub. No.: US 2026/0202455 A1
(43) Pub. Date: Jul. 16, 2026

(54) SELF-CHECKING FAULT DIAGNOSIS SYSTEM AND METHOD THEREOF

(71) Applicant: AUTOMOTIVE RESEARCH & TESTING CENTER, Changhua Hsien (TW)

(72) Inventors: Chien-An Chen, Changhua Hsien (TW); Chih-Wei Chuang, Changhua Hsien (TW)

(21) Appl. No.: 19/026,321

(22) Filed: Jan. 16, 2025

(51) Int. Cl. G01R 31/00

(52) U.S. Cl. CPC G01R 31/007

(57) ABSTRACT

A self-checking fault diagnosis system comprises sensors, a storage, and a processor. The sensors output sense data. At least one first sense data and at least one second sense data are defined from the sense data. The storage stores at least one second historical sense data corresponding to the second sense data. The processor is connected to the sensors and the storage, performs a first AI model to output at least one first prediction data according to the second sense data, and performs a second AI model to output at least one second prediction data according to the second historical sense data and the first prediction data. When the processor determines that differences between the first sense data and the first prediction data and between the second sense data and the second prediction data are respectively within tolerable ranges, the processor outputs a notification message indicating pass of self-checking.

### BACKGROUND OF THE INVENTION

### 1. Field of the Invention

The present invention relates generally to a fault diagnosis system and a method thereof, and more particularly to a self-checking fault diagnosis system and a method thereof.

### 2. Description of Related Art

With the development of Artificial Intelligence (AI) technology, the conventional art can utilize a processor to perform an AI model. After the AI model receives sense data from multiple sensors, the AI model can perform the fault diagnosis based on the sense data. However, the reason that the conventional art can trust the fault diagnosis result made by the AI model performed by the processor is mainly based on the normal operation of the multiple sensors and the AI model. However, as time goes on, the multiple sensors may have abnormalities (such as being out of order), or the AI model may have computation abnormalities, making the fault diagnosis result made by the AI model inaccurate. For example, the fault diagnosis result made by the AI model is normal (pass) under the condition that the sensor or the AI model has been abnormal. Therefore, when the back end application is still proceeding according to the fault diagnosis result made by the abnormal AI model and/or the abnormal sensors, damage would occur.

### SUMMARY OF THE INVENTION

An objective of the present invention is to provide a self-checking fault diagnosis system and a method thereof to overcome the problem that the back end application is still proceeding according to the diagnosis result while the sensors or the AI model is abnormal.

The self-checking fault diagnosis system of the present invention comprises:
multiple sensors respectively outputting multiple sense data in real time, wherein at least one first sense data and at least one second sense data are defined from the multiple sense data;
a storage storing at least one second historical sense data corresponding to the at least one second sense data;
a processor signally connected to the multiple sensors and the storage and performing:
   a first AI model to output at least one first prediction data according to the at least one second sense data; and
   a second AI model to output at least one second prediction data according to the at least one second historical sense data and the at least one first prediction data;
wherein when the processor determines that a difference between the at least one first sense data and the at least one first prediction data is within a first tolerable range and a difference between the at least one second sense data and the at least one second prediction data is within a second tolerable range, the processor outputs a notification message indicating pass of self-checking.

The self-checking fault diagnosis method of the present invention is performed by a processor and comprises:
step A: receiving multiple sense data in real time, wherein at least one first sense data and at least one second sense data are defined from the multiple sense data;
step B: outputting at least one first prediction data by a first AI model according to the at least one second sense data;
step C: determining whether a difference between the at least one first sense data and the at least one first prediction data is within a first tolerable range;
step D: outputting at least one second prediction data by a second AI model according to at least one second historical sense data and the at least one first prediction data when the difference between the at least one first sense data and the at least one first prediction data is within the first tolerable range;
step E: determining whether a difference between the at least one second sense data and the at least one second prediction data is within a second tolerable range; and
step F: outputting a notification message indicating pass of self-checking when the difference between the at least one second sense data and the at least one second prediction data is within the second tolerable range.

In conclusion, in the present invention, when the processor determines that the difference between the at least one first sense data and the at least one first prediction data is within a first tolerable range and the difference between the at least one second sense data and the at least one second prediction data is within the second tolerable range, the processor outputs the notification message indicating pass of self-checking.

In contrast, when the processor determines that the difference between the at least one first sense data and the at least one first prediction data is not within a first tolerable range or the difference between the at least one second sense data and the at least one second prediction data is not within the second tolerable range, which means the multiple sensors, the first AI model, or the second AI model may become abnormal, the processor then accordingly outputs a warning message (such as a model-to-be-corrected message, a second-sensor-abnormal message, and a first-sensor-abnormal message) to achieve the self-checking purpose for the multiple sensors, the first AI model, and the second AI model. The processor can also implement a corresponding response according to the warning message for the abnormality.

### BRIEF DESCRIPTION OF THE DRAWINGS

FIG. 1 is a block diagram of the self-checking fault diagnosis system of the present invention.

FIG. 2 is a flow chart of steps A to F of the self-checking fault diagnosis method of the present invention.

FIG. 3 is a block diagram of the first AI model corresponding to step B of the method of the present invention.

FIG. 4 is a block diagram of the second AI model corresponding to step D of the method of the present invention.

FIG. 5 is a flow chart of steps G to J of the self-checking fault diagnosis method of the present invention.

FIG. 6 is a block diagram of the first AI model corresponding to step G of the method of the present invention.

FIG. 7 is a flow chart of steps K to Q of the self-checking fault diagnosis method of the present invention.

FIG. 8 is a block diagram of the second AI model corresponding to step N of the method of the present invention.

### DETAILED DESCRIPTION OF PREFERRED EMBODIMENT(S)

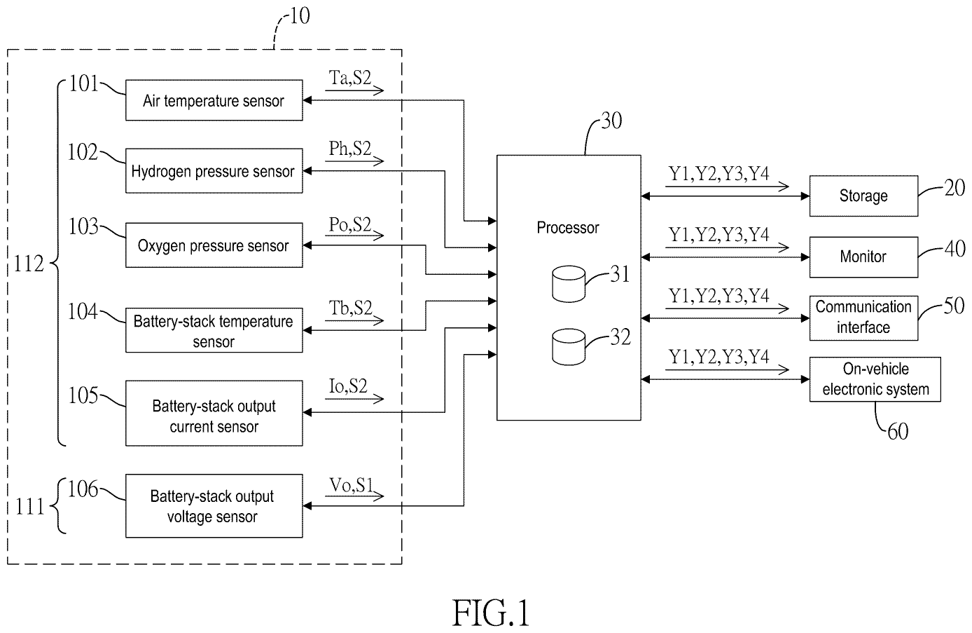

With reference to FIG. 1, the self-checking fault diagnosis system of the present invention comprises multiple sensors, a storage 20 and a processor 30. An embodiment described below of the present invention is applicable for an on-vehicle fuel cell system. Besides, the present invention is also applicable for any other fault diagnosis which uses sensors and Artificial Intelligence (AI) computation model. For example, in addition to the foregoing on-vehicle fuel cell system, the present invention is also applicable for ADAS (advanced driver assistance systems), or a predictive boiler maintenance system that can reduce outage frequency, or a wind power generation system that can simulate wind field changes and improve wind turbine power generation efficiency, or a method for estimating material properties. In other words, the applicable fields of the present invention comprise chemical industry, aerospace industry, heat dissipation design for electronic components, biomedicine industry, computer graphics (CG), and so on. For example, when the present invention is applied to the foregoing ADAS, the multiple sensors may comprise a sensor that senses lane mark, such as a camera to capture the image of the lane mark. So, the sense data of the sensor is the lane mark image at present. The AI model is configured to recognize the lane mark of the image. Or, the multiple sensors may comprise a sensor to position the location (coordinate) of the vehicle, such as a positioning device. So, the sense data of the sensor may be actual positioning signals of the GNSS (Global Navigation Satellite System, GNSS) at present. The AI model is configured to recognize the positioning information.

The multiple sensors are mounted on and/or electrically connected to a fuel cell electric generator 10 of a vehicle. So, the object of the multiple sensors is the operating status of the fuel cell electric generator 10. The multiple sensors can output sense data of the fuel cell electric generator 10 in real time. For example, the multiple sensors may comprise an air temperature sensor 101, a hydrogen pressure sensor 102, an oxygen pressure sensor 103, a battery-stack temperature sensor 104, a battery-stack output current sensor 105, and a battery-stack output voltage sensor 106. Correspondingly, the multiple sense data outputted by the multiple sensors respectively are an air temperature Ta, a hydrogen pressure Ph, an oxygen pressure Po, a battery-stack temperature Tb, a battery-stack output current Io, and a battery-stack output voltage Vo of the fuel cell electric generator 10. The installation and the measurement principle of the multiple sensors to the fuel cell electric generator 10 are common knowledge in the related art and would not be described herein.

For conciseness in description, at least one first sensor 111 is defined from the multiple sensors. The rest of the sensor(s) except the at least one first sensor 111 is/are defined as at least one second sensor 112. In general, the amount of the at least one second sensor 112 is more than the amount of the at least one first sensor 111. But the at least one first sensor 111 and the at least one second sensor 112 are not limited to the foregoing amounts. In an embodiment of the present invention, the at least one first sensor 111 is the battery-stack output voltage sensor 106, and the second sensors 112 comprise the air temperature sensor 101, the hydrogen pressure sensor 102, the oxygen pressure sensor 103, the battery-stack temperature sensor 104, and the battery-stack output current sensor 105. Correspondingly, the sense data outputted by the first sensor 111 is defined as a first sense data S1 (such as the battery-stack output voltage Vo), and the sense data outputted by the second sensors 112 is defined as a second sense data S2 (such as the air temperature Ta, the hydrogen pressure Ph, the oxygen pressure Po, the battery-stack temperature Tb, and the battery-stack output current Io). Besides, in the following description, the term “sense data” may have special definition in accordance with time points.

The storage 20 is to store data. For example, the storage 20 may be a hard disk drive (HDD), a solid-state drive (SSD), a memory, or a memory card.

The processor 30 may be a chip of central processing unit (CPU) or may further comprise a chip of graphic processing unit (GPU). The CPU and the GPU may collaborate with each other. The processor 30 is signally connected to the multiple sensors and the storage 20 via signal cable(s) and/or data bus for example. So, the processor 30 can receive the sense data from the multiple sensors in real time and access the data of the storage 20. In other words, the processor 30 can store the sense data in the storage 20, and read the stored sense data from the storage 20. After the sense data is just stored in the storage 20 and when the processor 30 receives the latest sense data at a next time point, the sense data just stored in the storage 20 at a prior time point is defined as historical sense data.

The processor 30 performs program data of a first AI model 31 and a second AI model 32. The program data of the first AI model 31 and the second AI model 32 may be stored in the storage 20 for the processor 30 to access. In an embodiment of the present invention, the first AI model 31 and the second AI model 32 may be neural network models. Please note that the present invention just involves the application of the AI models. The principle of the AI models may refer to the following disclosures and would not be described in detail herein.
1. Wuhan University of Technology, 2011 PhD dissertation: Research on several key issues in fault diagnosis and maintenance of vehicle fuel cell systems; Author: Quan Rui (machine-translated by Google), which can be downloaded from the URL “https://apps.wanfangdata.com.cn/thesis/article:Y1948776”.
2. Hubei University of Technology, 2021 Master's thesis: Research on on-board fuel cell system monitoring and fault diagnosis system. Author: Xie Song (machine-translated by Google), which can be downloaded from the URL “https://d.wanfangdata.com.cn/thesis/D02361133”.
3. Taiyuan University of Technology, 2021 Master's thesis: Research on the design and fault diagnosis method of hydrogen fuel cell safety monitoring system. Author: Liu Ao (machine-translated by Google), which can be downloaded from the URL “https://d.wanfangdata.com.cn/thesis/d02475540”.

As mentioned above, the sense data outputted by the first sensor 111 is defined as the first sense data S1, and the sense data outputted by the second sensors 112 is defined as the second sense data S2. In an embodiment of the present invention, the first AI model 31 outputs at least one first prediction data according to the at least one second sense data S2. In the training of the first AI model 31, the training data comprises multiple sets of sense data (each set corresponds to a same time point) that are actually measured and collected from the fuel cell electric generator 10. Each set of the training data may comprise air temperature, hydrogen pressure, oxygen pressure, battery-stack temperature, battery-stack output current, and battery-stack output voltage. The air temperature, the hydrogen pressure, the oxygen pressure, the battery-stack temperature, and the battery-stack output current in one set would be input training samples for the first AI model 31, and the battery-stack output voltage in the same set would be output training sample for the first AI model 31. After the first AI model 31 completes the training and operates on line, the processor 30 uses the air temperature Ta, the hydrogen pressure Ph, the oxygen pressure Po, the battery-stack temperature Tb, and the battery-stack output current Io as the second sense data S2 as well as the input data for the first AI model 31. In other words, in the present invention, the at least one second sensor 112 would be defined from the multiple sensors according to the input data items of the first AI model 31. Correspondingly, the first AI model 31 may output a predictive battery-stack output voltage as the first prediction data. In other words, in the present invention, the at least one first sensor 111 would be defined from the multiple sensors according to the output data items of the first AI model 31.

In the training of the second AI model 32, the training data comprises multiple sets of sense data (each set corresponding to a same time point) that are actually measured and collected from the fuel cell electric generator 10. Each set of the training data may comprise air temperature, hydrogen pressure, oxygen pressure, battery-stack temperature, battery-stack output current, and battery-stack output voltage. In the following description, for two sets of sense data on adjacent two time points, the term “k” indicates one set of sense data on a time point, and the term “k-1” indicates the other set of sense data on a prior time point. So, the air temperature (k-1), the hydrogen pressure (k-1), the oxygen pressure (k-1), the battery-stack temperature (k-1), the battery-stack output current (k-1), and the battery-stack output voltage (k-1) in one set would be input training samples for the second AI model 32, and the air temperature (k), the hydrogen pressure (k), the oxygen pressure (k), the battery-stack temperature (k), and the battery-stack output current (k) in the other set would be output training samples for the second AI model 32. After the second AI model 32 completes the training and operates on line, the processor 30 reads the air temperature at a prior time point, the hydrogen pressure at the prior time point, the oxygen pressure at the prior time point, the battery-stack temperature at the prior time point, and the battery-stack output current at the prior time point from the storage 20 as multiple second historical sense data. The processor 30 uses the multiple second historical sense data as basis and further uses the sense data (such as the battery-stack output voltage Vo received from the battery-stack output voltage sensor 106) or the first prediction data (such as the predictive battery-stack output voltage outputted by the first AI model 31) as the input data for the second AI model 32. Correspondingly, the second AI model 32 may output a predictive air temperature, a predictive hydrogen pressure, a predictive oxygen pressure, a predictive battery-stack temperature, and a predictive battery-stack output current as multiple second prediction data. Hence, the second AI model 32 may output at least one second prediction data according to the at least one second historical sense data and the at least one sense data or the at least one first prediction data.

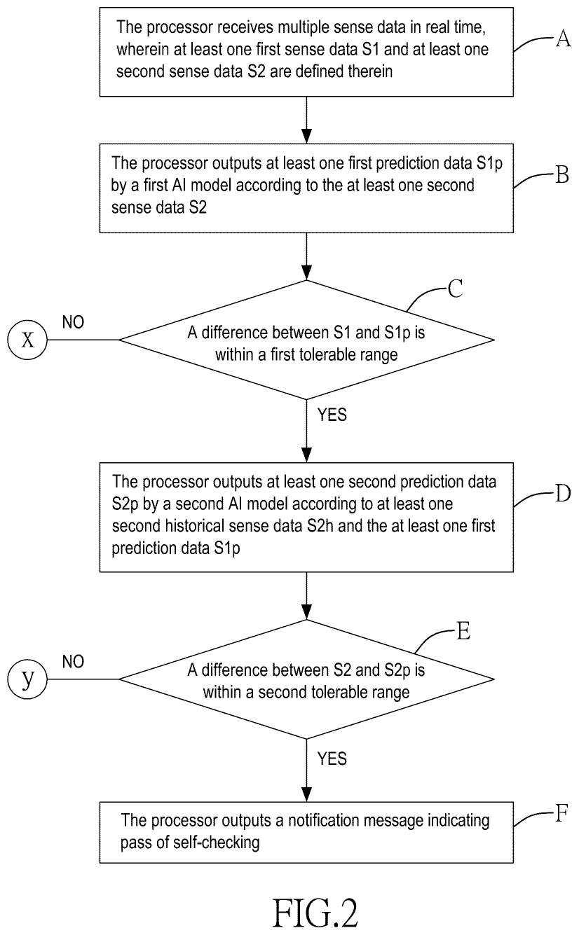

With reference to FIG. 1 and FIG. 2, the self-checking fault diagnosis method of the present invention is described as follows.

Step A: The processor 30 receives the multiple sense data from the multiple sensors in real time. At least one first sense data S1 and at least one second sense data S2 are defined from the multiple sense data. In the embodiment of the present invention, the at least one first sense data S1 is the battery-stack output voltage Vo, and the at least one second sense data S2 comprises the air temperature Ta, the hydrogen pressure Ph, the oxygen pressure Po, the battery-stack temperature Tb, and the battery-stack output current Io.

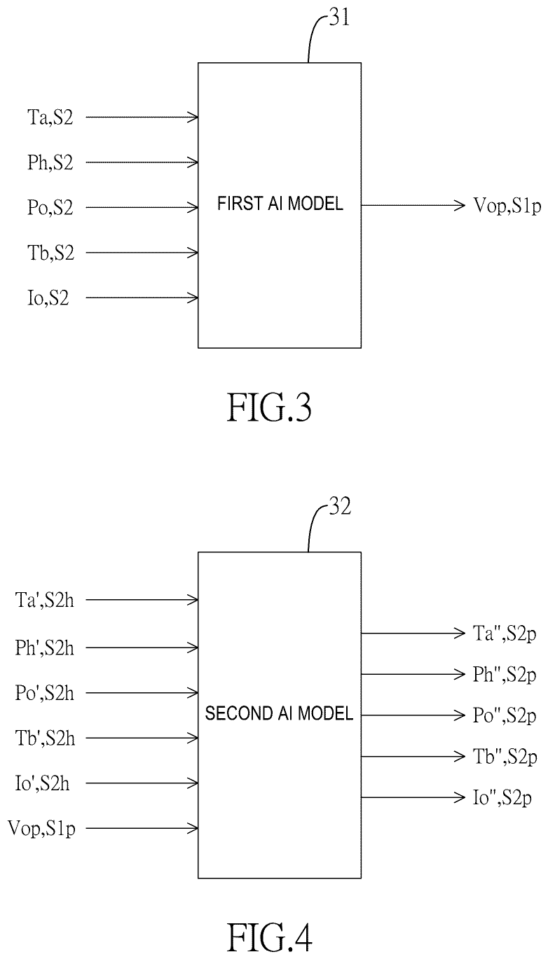

Step B: With reference to FIG. 3, the processor 30 outputs the at least one first prediction data S1p by the first AI model 31 according to the at least one second sense data S2. In the embodiment of the present invention, the first prediction data S1p is the predictive battery-stack output voltage Vop.

Step C: The processor 30 determines whether a difference between the at least one first sense data S1 and the at least one first prediction data S1p is within a tolerable range (hereinafter referred to as a first tolerable range). The processor 30 is preset with thresholds corresponding to the multiple sensors respectively. The thresholds are adjustable predetermined values. Specifically, the difference lower than or equal to the threshold represents that the difference is within the first tolerable range. In contrast, the difference higher than the threshold represents that the difference is not within the first tolerable range. In the embodiment of the present invention, the processor 30 determines whether a voltage difference between the battery-stack output voltage Vo and the predictive battery-stack output voltage Vop is lower than or equal to a first threshold. If the determination result of the step C is Yes, which means the foregoing voltage difference is within the first tolerable range, the processor 30 will proceed to the step D as described below.

Step D: With reference to FIG. 4, the processor 30 outputs the at least one second prediction data S2p by the second AI model 32 according to the at least one second historical sense data S2h and the at least one first prediction data S1p. In the embodiment of the present invention, when the processor 30 determines that the voltage difference between the battery-stack output voltage Vo and the predictive battery-stack output voltage Vop is lower than or equal to the first threshold, the processor 30 outputs a predictive air temperature Ta″, a predictive hydrogen pressure Ph″, a predictive oxygen pressure Po″, a predictive battery-stack temperature Tb″, and a predictive battery-stack output current Io″ (the second prediction data S2p) according to a prior air temperature Ta′, a prior hydrogen pressure Ph′, a prior oxygen pressure Po′, a prior battery-stack temperature Tb′, and a prior battery-stack output current Io′ (the second historical sense data S2h) and a prior battery-stack output voltage Vop (the first prediction data S1p) read from the storage 20.

Step E: The processor 30 determines whether a difference between the at least one second sense data S2 and the at least one second prediction data S2p is within a tolerable range (hereinafter referred to as a second tolerable range). As mentioned in the step C, the processor 30 is preset with the thresholds corresponding to the multiple sensors respectively. In the embodiment of the present invention, the processor 30 determines whether a temperature difference between the air temperature Ta and the predictive air temperature Ta″ is lower than or equal to a second threshold, determines whether an air pressure difference between the hydrogen pressure Ph and the predictive hydrogen pressure Ph″ is lower than or equal to a third threshold, determines whether an air pressure difference between the oxygen pressure Po and the predictive oxygen pressure Po″ is lower than or equal to a fourth threshold, determines whether a temperature difference between the battery-stack temperature Tb and the predictive battery-stack temperature Tb″ is lower than or equal to a fifth threshold, and determines whether a current difference between the battery-stack output current Io and the predictive battery-stack output current Io″ is lower than or equal to a sixth threshold. When the processor 30 determines that the differences between the second sense data S2 and the second prediction data S2p are respectively within their tolerable ranges, the processor 30 proceeds to the step F as described below

Step F: When the processor 30 determines that the difference between the at least one second sense data S2 and the at least one second prediction data S2p is within the second tolerable range, the processor 30 outputs a notification message Y1 indicating pass of self-checking. In the embodiment of the present invention, because the processor 30 in the foregoing step C determines that the voltage difference between the battery-stack output voltage Vo and the predictive battery-stack output voltage Vop is within the first tolerable range, which means the actual sense data by the battery-stack output voltage sensor 106 is consistent with the prediction data by the first AI model 31, the operating statuses of the battery-stack output voltage sensor 106 and the first AI model 31 are normal. Similarly, because the processor 30 in the foregoing step E determines that the second sense data S2 and the second prediction data S2p are within the second tolerable range, which means the actual sense data by the air temperature sensor 101, the hydrogen pressure sensor 102, the oxygen pressure sensor 103, the battery-stack temperature sensor 104, and the battery-stack output current sensor 105 is consistent with the prediction data by the second AI model 32, the operating statuses of the air temperature sensor 101, the hydrogen pressure sensor 102, the oxygen pressure sensor 103, the battery-stack temperature sensor 104, and the battery-stack output current sensor 105, and the second AI model 32 are normal. Therefore, the information of the pass of self-checking indicated by the notification message Y1 represents that the operation statuses of all of the multiple sensors, the first AI model 31, and the second AI model 32 are normal.

In conclusion, when the processor 30 determines that the difference between the at least one sense data S1 and the at least one first prediction data S1p is within the first tolerable range (the determination result of the step C is Yes) and the difference between the at least one second sense data S2 and the at least one second prediction data S2p is within the second tolerable range (the determination result of the step E is Yes), the processor 30 outputs the notification message Y1 indicating pass of self-checking.

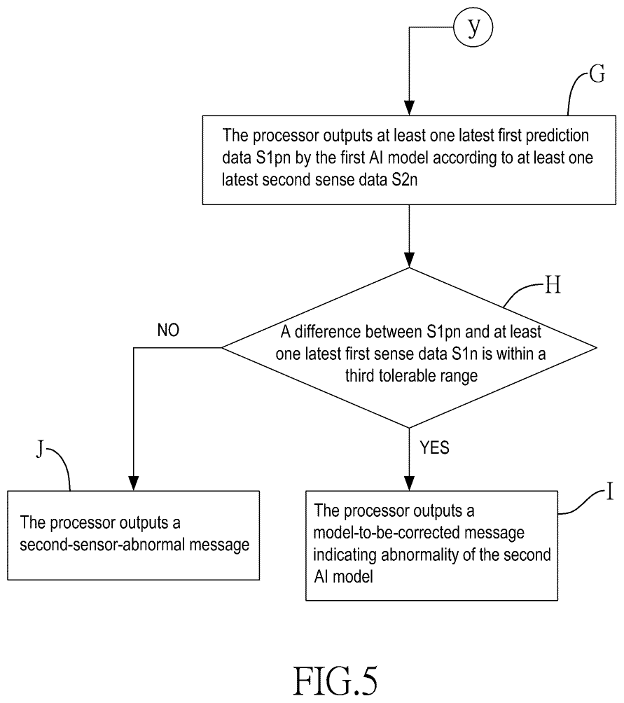

In the step E, with reference to FIG. 2 and FIG. 5, when the processor 30 determines that the difference between the at least one sense data and the at least one second prediction data is not within the second tolerable range, the processor 30 proceeds to the step G as described below.

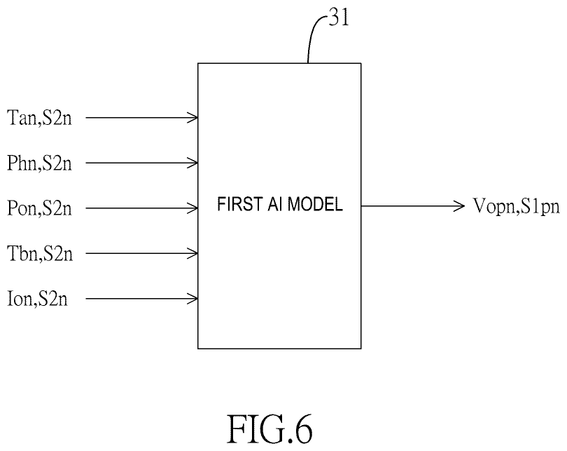

Step G: Because the processor 30 continuously receives the sense data from the multiple sensors respectively, the sense data received at a next time point is defined as latest sense data. With reference to FIG. 6, the processor 30 can output at least one latest first prediction data S1pn by the first AI model 31 according to at least one latest second sense data S2n, and then proceeds to step H as described below. In the embodiment of the present invention, the processor 30 outputs a latest predictive battery-stack output voltage Vopn by the first AI model 31 according to a latest air temperature Tan, a latest hydrogen pressure Phn, a latest oxygen pressure Pon, a latest battery-stack temperature Tbn, and a latest battery-stack output current Ion that are received at a next time point.

Step H: The processor 30 determines whether a difference between the at least one latest first prediction data S1pn and at least one latest first sense data S1n is within a tolerable range (hereinafter referred to as a third tolerable range). In the embodiment of the present invention, the processor 30 determines whether a voltage difference between the latest predictive battery-stack output voltage Vopn and a latest battery-stack output voltage Von which is received at a next time point is lower than or equal to the first threshold.

If the determination result of the step H is Yes, which means the operating status of the second AI model 32 is abnormal (the reason is that the difference determined in the step E is not within the tolerable range), the processor 30 outputs a model-to-be-corrected message Y2 indicating abnormality of the second AI model 32 (as step I shown in FIG. 5).

If the determination result of the step H is No, which means the at least one second sensor 112 is abnormal (such as being out of order) resulting in that the differences determined in the steps E and H are not within the tolerable ranges, the processor 30 outputs a second-sensor-abnormal message Y3 (as step J shown in FIG. 5) indicating abnormality of the at least one second sensor 112.

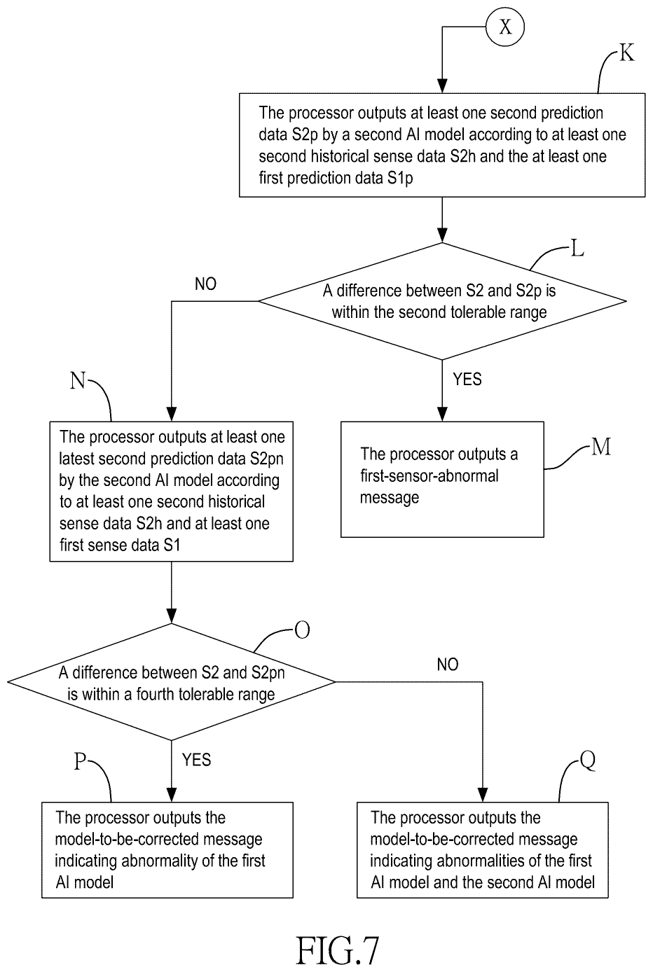

In the step C, with reference to FIG. 2 and FIG. 7, when the processor 30 determines that the difference between the at least one first sense data S1 and the at least one first prediction data S1p is not within the first tolerable range, that is to say, the determination result of the step C is No, and the processor 30 proceeds to step K and step L as described below.

Step K: The processor 30 outputs the at least one second prediction data S2p by the second AI model 32 according to the at least one second historical sense data S2h and the at least one first prediction data S1p. The step K would refer to the foregoing step D and not be repeatedly described herein.

Step L: The processor 30 determines whether the difference between the at least one second sense data S2 and the at least one second prediction data S2p is within the second tolerable range. The step L can refer to the foregoing step E and would not repeatedly described herein.

If the determination result of the step L is Yes, which means the at least one first sensor 111 is abnormal (such as being out of order), resulting in that the difference determined in the step C is not within the tolerable ranges, the processor 30 outputs a first-sensor-abnormal message Y4 (as step M shown in FIG. 7) indicating abnormality of the at least one first sensor 111. In the embodiment of the present invention, the first-sensor-abnormal message Y4 indicates abnormality of the battery-stack output voltage sensor 106. If the determination result of the step L is No, the processor 30 proceeds to the step N as described below.

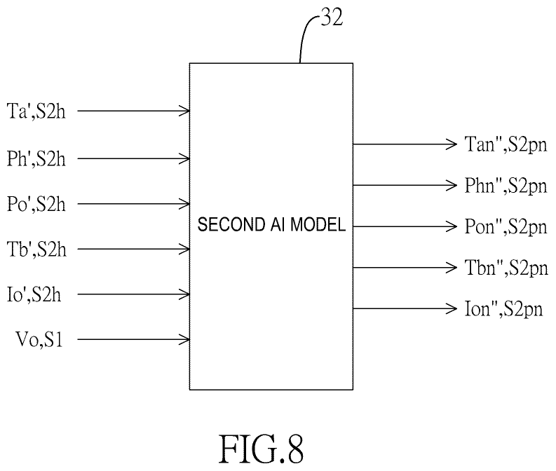

Step N: The processor 30 outputs at least one latest second prediction data S2pn by the second AI model 32 according to the at least one second historical sense data S2h and the at least one first sense data S1. With reference to FIG. 8, in the embodiment of the present invention, the at least one second historical sense data S2h inputted to the second AI model 32 comprises a prior air temperature Ta′, a prior hydrogen pressure Ph′, a prior oxygen pressure Po′, a prior battery-stack temperature Tb′, and a prior battery-stack output current Io′ that are received on a prior time point. The at least one first sense data S1 inputted to the second AI model 32 is the battery-stack output voltage Vo. The at least one latest second prediction data S2pn outputted by the second AI model 32 comprises a latest predictive air temperature Tan″, a latest predictive hydrogen pressure Phn″, a latest predictive oxygen pressure Pon″, a latest predictive battery-stack temperature Tbn″, and a latest predictive battery-stack output current Ion″. In comparison between the step N (also referring to FIG. 8) and the step D (also referring to FIG. 4), the at least one first prediction data S1p inputted to the second AI model 32 in FIG. 4 is replaced with the at least one first sense data S1 in FIG. 8.

Step O: The processor 30 determines whether a difference between the at least one latest second prediction data S2pn and the at least one second sense data S2 is within a tolerable range (hereinafter referred to as a fourth tolerable range). As mentioned in the step C, the processor 30 is preset with the thresholds corresponding to the multiple sensors respectively. In the embodiment of the present invention, the processor 30 determines whether a temperature difference between the air temperature Ta and the latest predictive air temperature Tan″ is lower than or equal to the second threshold, determines whether an air pressure difference between the hydrogen pressure Ph and the latest predictive hydrogen pressure Phn″ is lower than or equal to the third threshold, determines whether an air pressure difference between the oxygen pressure Po and the latest predictive oxygen pressure Pon″ is lower than or equal to the fourth threshold, determines whether a temperature difference between the battery-stack temperature Tb and the latest predictive battery-stack temperature Tbn″ is lower than or equal to the fifth threshold, and determines whether a current difference between the battery-stack output current Io and the latest predictive battery-stack output current Ion″ is lower than or equal to the sixth threshold.

If the determination result of the step O is Yes, the processor 30 outputs the model-to-be-corrected message Y2 indicating abnormality of the first AI model 31 (as step P shown in FIG. 7). In the embodiment of the present invention, when the difference between the second sense data S2 and the second prediction data S2pn is within the tolerable range, that means the operating status of the second AI model 32 is normal but the operating status of the first AI model 31 is abnormal. The reason is that the determination result of the earlier step C is No and cross checked by the steps L and O. So, the processor 30 can determine the first AI model 31 is abnormal.

If the determination result of the step O is No, the processor 30 outputs the model-to-be-corrected message Y2 indicating abnormalities of the first AI model 31 and the second AI model 32 (as step Q shown in FIG. 7). In the embodiment of the present invention, based on the determination result of the earlier step C is No and cross checked by the steps L and O, when the difference between the second sense data S2 and the second prediction data S2pn is not within the tolerable range, the processor 30 can determine the first AI model 31 and the second AI model 32 are abnormal.

The above-mentioned notification message Y1, model-to-be-corrected message Y2, second-sensor-abnormal message Y3, and first-sensor-abnormal message Y4 are usable information for back end to respond to the abnormality. For example, with reference to FIG. 1, the processor 30 may be electrically connected to a monitor 40, a communication interface 50, and/or an on-vehicle electronic system 60 of the vehicle. The monitor 40 may be a dashboard display or a center information display for example. The communication interface 50 may be a Bluetooth communication interface, a WiFi communication interface, or a mobile communication interface for example. The on-vehicle electronic system 60 may be a braking system, a speed control system, or a steering system for example. The processor 30 can store the foregoing messages Y1, Y2, Y3, Y4 in the storage 20 for future reference, display the foregoing messages Y1, Y2, Y3, Y4 on the monitor 40 via light signals or images, or transmit the foregoing messages Y1, Y2, Y3, Y4 to a smart phone or a cloud server via the communication interface 50. The processor 30 can control the on-vehicle electronic system 60 to intervene the driving operation of the vehicle according to the model-to-be-corrected message Y2, the second-sensor-abnormal message Y3, and the first-sensor-abnormal message Y4, for example, to slow down the vehicle or to park the vehicle at road side. Hence, when the multiple sensors, the first AI model 31, and/or the second AI model 32 is/are abnormal, the vehicle would be prevented from driving.

What is claimed is:

1. A self-checking fault diagnosis system comprising:
multiple sensors respectively outputting multiple sense data in real time, wherein at least one first sense data and at least one second sense data are defined from the multiple sense data;
a storage storing at least one second historical sense data corresponding to the at least one second sense data;
a processor signally connected to the multiple sensors and the storage and performing:
a first artificial intelligence (AI) model to output at least one first prediction data according to the at least one second sense data; and
a second AI model to output at least one second prediction data according to the at least one second historical sense data and the at least one first prediction data;
wherein when the processor determines that a difference between the at least one first sense data and the at least one first prediction data is within a first tolerable range and a difference between the at least one second sense data and the at least one second prediction data is within a second tolerable range, the processor outputs a notification message indicating pass of self-checking.

2. The system as claimed in claim 1, wherein when the processor determines that the difference between the at least one first sense data and the at least one first prediction data is within the first tolerable range and the difference between the at least one second sense data and the at least one second prediction data is not within the second tolerable range, the processor outputs at least one latest first prediction data by the first AI model according to at least one latest second sense data and determines whether a difference between the at least one latest first prediction data and at least one latest first sense data is within a third tolerable range;
if Yes, the processor outputs a model-to-be-corrected message indicating abnormality of the second AI model; and
if No, the processor outputs a second-sensor-abnormal message.

3. The system as claimed in claim 2, wherein when the processor determines that the difference between the at least one first sense data and the at least one first prediction data is not within the first tolerable range and the difference between the at least one second sense data and the at least one second prediction data is within the second tolerable range, the processor outputs a first-sensor-abnormal message.

4. The system as claimed in claim 3, wherein the processor determines that the difference between the at least one first sense data and the at least one first prediction data is not within the first tolerable range and the difference between the at least one second sense data and the at least one second prediction data is not within the second tolerable range, the processor outputs at least one latest second prediction data by the second AI model according to the at least one second historical sense data and the at least one first sense data and determines whether a difference between the at least one latest second prediction data and the at least one second sense data is within a fourth tolerable range;
if Yes, the processor outputs the model-to-be-corrected message indicating abnormality of the first AI model; and
if No, the processor outputs the model-to-be-corrected message indicating abnormalities of the first AI model and the second AI model.

5. A self-checking fault diagnosis method, performed by a processor and comprising:
step A: receiving multiple sense data in real time, wherein at least one first sense data and at least one second sense data are defined from the multiple sense data;
step B: outputting at least one first prediction data by a first AI model according to the at least one second sense data;
step C: determining whether a difference between the at least one first sense data and the at least one first prediction data is within a first tolerable range;
step D: outputting at least one second prediction data by a second AI model according to at least one second historical sense data and the at least one first prediction data when the difference between the at least one first sense data and the at least one first prediction data is within the first tolerable range;
step E: determining whether a difference between the at least one second sense data and the at least one second prediction data is within a second tolerable range; and
step F: outputting a notification message indicating pass of self-checking when the difference between the at least one second sense data and the at least one second prediction data is within the second tolerable range.

6. The method as claimed in claim 5, wherein in the step E, when the processor determines that the difference between the at least one second sense data and the at least one second prediction data is not within the second tolerable range, the processor further performs steps as follows:
step G: outputting at least one latest first prediction data by the first AI model according to at least one latest second sense data; and
step H: determining whether a difference between the at least one latest first prediction data and at least one latest first sense data is within a third tolerable range;
step I: if Yes, the processor outputs a model-to-be-corrected message indicating abnormality of the second AI model; and
step J: if No, the processor outputs a second-sensor-abnormal message.

7. The method as claimed in claim 6, wherein in the step C, when the processor determines that the difference between the at least one first sense data and the at least one first prediction data is not within the first tolerable range, the processor further performs steps as follows:
step K: outputting the at least one second prediction data by the second AI model according to the at least one second historical sense data and the at least one first prediction data;
step L: determining whether the difference between the at least one second sense data and the at least one second prediction data is within the second tolerable range;
step M: outputting a first-sensor-abnormal message when the difference between the at least one second sense data and the at least one second prediction data is within the second tolerable range.

8. The method as claimed in claim 7, wherein in the step L, when the processor determines that the difference between the at least one second sense data and the at least one second prediction data is not within the second tolerable range, the processor further performs steps as follows:
step N: outputting at least one latest second prediction data by the second AI model according to the at least one second historical sense data and the at least one first sense data;
step O: determining whether a difference between the at least one latest second prediction data and the at least one second sense data is within a fourth tolerable range;
step P: if Yes, the processor outputs the model-to-be-corrected message indicating abnormality of the first AI model; and
step Q: if No, the processor outputs the model-to-be-corrected message indicating abnormalities of the first AI model and the second AI model.
